(19) United States
(12) Patent Application Publication
(10) Pub. No.: US 2026/0136841 A1
(43) Pub. Date: May 14, 2026

(54) Fabrication of Single Crystalline Body-centered-cubic Tantalum Thin Films on a-plane Sapphire Substrates

(71) Applicant: US Department of Energy, Washington, DC (US)

(72) Inventor: Mingzhao Liu, Syosset, NY (US)

(21) Appl. No.: 18/941,058

(22) Filed: Nov. 8, 2024

(51) Int. Cl. H10N 60/01

(52) U.S. Cl. CPC H10N 60/0912

(57) ABSTRACT

One or more embodiments relates to a method for producing thin film tantalum (Ta) on a substrate. The method includes cleaning the substrate, removing organic contaminants, forming a cleaned substrate; and heating the cleaned substrate to a predetermined first temperature for a predetermined first period of time, forming a stabilized cleaned substrate. Embodiments include igniting a first RF plasma around the stabilized cleaned substrate at a predetermined first power; and igniting a second RF plasma around the stabilized cleaned substrate at a predetermined second power. The method includes depositing Ta on the stabilized cleaned substrate at a predetermined deposition rate for a predetermined second period of time, forming a substrate having a Ta film of a predetermined thickness; and cooling the substrate having a Ta film of the predetermined thickness for a predetermined third period of time, producing a fully epitaxial thin film (Ta) on the substrate.

### STATEMENT OF GOVERNMENT INTEREST

The United States Government has rights in this invention pursuant to Contract No. DESC0012704 between the U.S. Department of Energy and Brookhaven National Laboratory.

### PRIOR ART

Mun, Junsik, Sushko, Peter V., Brass, Emma, Zhou, Chenyu, Kisslinger, Kim, Qu, Xiaohui, Liu, Mingzhao, and Zhu, Yimei. Probing Oxidation-Driven Amorphized Surfaces in a Ta(110) Film for Superconducting Qubit. United States: N. p., 2023. Web. doi: 10.1021/acsnano.3c10740.
New material platform for superconducting transmon qubits with coherence times exceeding 0.3 milliseconds,” A. P. M. Place, L. V. H. Rodgers, P. Mundada, B. M. Smitham, M. Fitzpatrick, Z. Leng, A. Premkumar, J. Bryon, A. Vrajitoarea, S. Sussman, G. Cheng, T. Madhavan, H. K. Babla, X. H. Le, Y. Gang, B. Jaeck, A. Gyenis, N. Yao, R. J. Cava, N. P. de Leon, A. A. Houck, Nature Communications 12, 1779 (2021)

### BACKGROUND OF THE INVENTION

Advances in quantum computing are largely dependent on advances in qubit technology. The transmon qubit has become the leading platform for quantum computing. That platform is based on an Al/AlOₓ/Al Josephson junction shunted to a large capacitor, which is further coupled to a high-Q microwave resonator. The shunting capacitor and the resonator are both fabricated from a thin film of superconductor (e.g., niobium) deposited by magnetron sputtering on an insulating substrate with low dielectric loss. For useful applications, it requires significant improvements in relaxation and coherence times, which are currently limited by relaxation channels in uncontrolled interfaces and contaminants. It was recently discovered that relaxation and coherence times exceeding 0.3 milliseconds could be achieved from 2-D transmon qubits by replacing niobium with body-centered-cubic (BCC) tantalum, i.e., α-Ta, in the device.

A need exists in the art for improving the coherence times of Ta-based qubits while simultaneously controlling or reducing surface oxidation.

### SUMMARY OF THE INVENTION

One object of at least one embodiment is related to a method of producing thin film tantalum (Ta) on a substrate. In one embodiment the method comprises cleaning the substrate, removing organic contaminants, forming a cleaned substrate; and heating the cleaned substrate to a predetermined first temperature for a predetermined first period of time, forming a stabilized cleaned substrate. The method includes igniting a first radio frequency (RF) plasma around the stabilized cleaned substrate at a predetermined first power, about 30 W for example; and igniting a second radio frequency (RF) plasma around the stabilized cleaned substrate at a predetermined second power, about 100 W for example. Additionally, the method includes depositing Ta on the stabilized cleaned substrate at a predetermined deposition rate for a predetermined second period of time, forming a substrate having a Ta film of a predetermined thickness; and cooling the substrate having a Ta film of the predetermined thickness for a predetermined third period of time, producing a fully epitaxial thin film (Ta) on the substrate.

In at least one embodiment the method includes unsealing a chamber and initializing the deposition of Ta on an a-plane of the substrate. In one or more embodiments cooling the substrate having the Ta film of the predetermined thickness for a predetermined third period of time, producing the fully epitaxial thin film (Ta) on the substrate includes leaving the substrate having the Ta film in a vacuum for the predetermined third period of time, about 150 minutes for example.

One or more embodiments include a sapphire substrate. In at least one embodiment, cleaning the substrate includes performing oxygen plasma ashing. Additional embodiments include heating the cleaned substrate further which includes loading the cleaned substrate into a chamber of a sputtering tool that has been pumped to a predetermined based pressure, about 3E⁻⁷ Torr or lower for example, and heating the cleaned substrate to the predetermined first temperature, between about 500° C. and 700° C. for example, for the predetermined first period of time, between about 10 and 30 minutes for example. In at least one embodiment, argon gas is introduced into the chamber at a stable flow rate changing the predetermined based pressure to a second predetermined pressure, between about 5 and 10 mTorr for example.

In one or more embodiments, Ta is deposited on the stabilized cleaned substrate at a predetermined deposition rate, between about 0.4 and 0.5 A/sec for example, for a predetermined second period of time, forming the substrate having the Ta film of the predetermined thickness comprises sealing the chamber for a fourth period of time, about 2 minutes for example.

In at least one embodiment, the method includes unsealing the chamber and initializing the deposition of Ta on an a-plane of the substrate. One or more embodiments includes cooling the substrate having the Ta film of the predetermined thickness for a predetermined third period of time, about 150 minutes for example, producing the fully epitaxial thin film (Ta) on the substrate comprises leaving the substrate having the Ta film in a vacuum for the predetermined third period of time.

Another object of at least one embodiment is related to a method for producing thin film on a substrate. The method includes dicing a crystal having a c-axis and an a-axis such that c-axis lies in an in-plane of the substrate and the a-axis lies perpendicular to the plane of the substrate; and depositing a thin film on the substrate such that the a-axis of the substrate is matched to a lattice of the thin film. In at least one embodiment, the thin film comprises an epitaxial α-Ta thin film and the substrate comprises an a-plane sapphire substrate.

One object of at least one embodiment is related to an insulating substrate used in a superconducting transom qubit. The insulating substrate includes at least an a-plane sapphire substrate and an epitaxial α-Ta thin film on the sapphire substrate. In at least one embodiment, the a-plane sapphire substrate has at least a c-axis lying in-plane sapphire substrate and an a-axis perpendicular to the sapphire surface. Th epitaxial α-Ta thin film on the sapphire substrate such that a-plane has a regular symmetry matted to a lattice plane of the α-Ta thin film.

### BRIEF DESCRIPTION OF DRAWINGS

The invention together with the above and other objects and advantages will be best understood from the following detailed description of the preferred embodiment of the invention shown in the accompanying drawings, wherein:

FIG. 1 depicts a cross-sectional high-angle annular dark-field scanning transmission electron microscopy (HAADF-STEM) image of the Ta film;

FIG. 2 depicts a graph illustrating an X-ray diffraction pattern showing the epitaxial growth of α-Ta on a-plane sapphire;

FIG. 3 depicts an illustration of the atomic arrangement at the interface between α-Ta and a-plane sapphire;

FIG. 4 depicts a flowchart illustrating a method for producing a thin film tantalum (Ta) on a substrate; and

FIG. 5 depicts a flowchart illustrating a method for producing thin film on a substrate.

### DETAILED DESCRIPTION OF THE INVENTION

The foregoing summary, as well as the following detailed description of certain embodiments of the present invention, will be better understood when read in conjunction with the appended drawings.

The following detailed description should be read with reference to the drawings in which similar elements in different drawings are numbered the same. The drawings, which are not necessarily to scale, depict illustrative embodiments and are not intended to limit the scope of the invention.

One or more embodiments relate to 2-D transmon qubits using body-centered-cubic (BCC) tantalum, i.e., α-Ta.

In at least one embodiment, the insulating substrate in transmon qubits has a dielectric loss that is as low as possible. Typically, sapphire (α-Al₂O₃) substrate is used for this purpose. The crystal of the sapphire has a trigonal symmetry and is anisotropic. Different substrates (wafers) of sapphire can be prepared by dicing a sapphire crystal at different angles with respect to the trigonal axis. In previous embodiments, niobium and BCC tantalum films are grown over c-plane sapphire, which is the most common way of sapphire dicing and has the trigonal axis (c-axis) perpendicular to its top surface, which is correspondingly named c-plane. Although α-Ta can be grown epitaxially over c-plane sapphire with the (110) lattice plane of α-Ta parallel to the c-plane, the microcrystals of α-Ta have two possible in-plane orientations due to the three-fold symmetry of sapphire c-plane. As a result, the α-Ta film grown as such contains numerous grain boundaries, which could serve as additional relaxation channels that prevent further improvement of qubit relaxation lifetime.

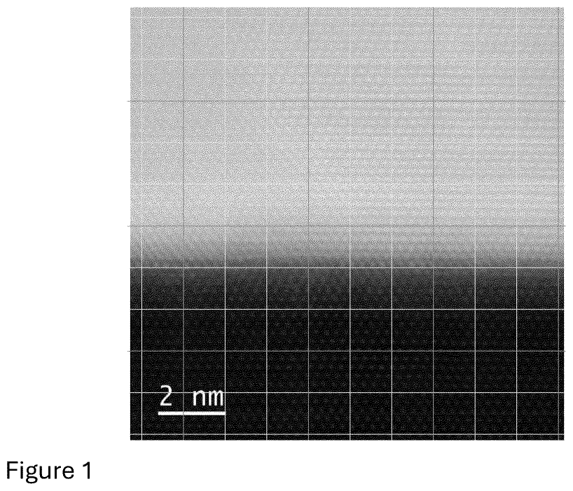

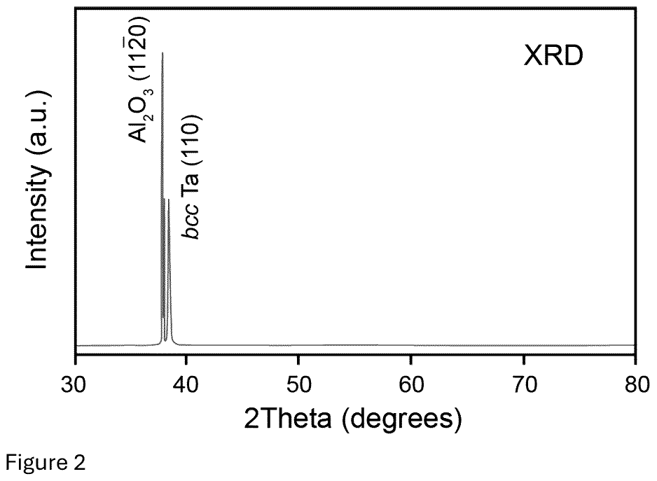

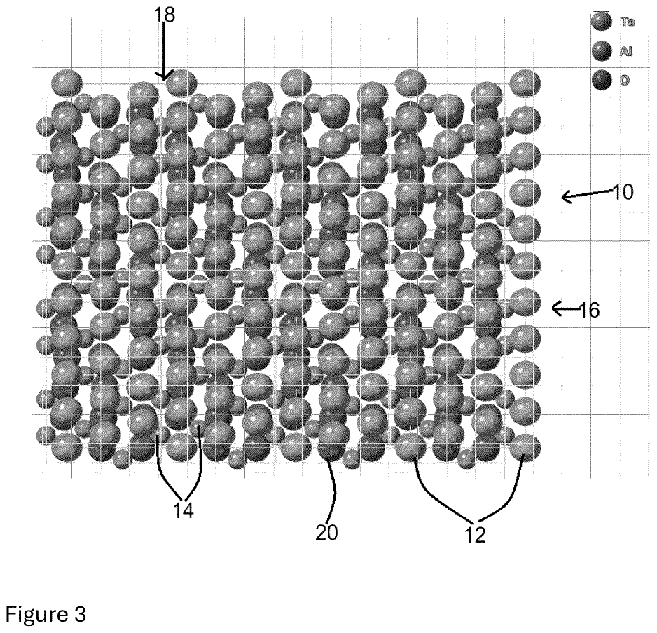

One or more embodiments relate to a method for producing fully epitaxial α-Ta thin film on a-plane sapphire substrate which, in one embodiment, is produced by dicing a sapphire crystal with the c-axis laying in-plane to the substrate surface but with the a-axis perpendicular to it. The corresponding top surface, i.e., the a-plane, has a rectangular symmetry that is better matched to the (110) lattice plane of α-Ta. Because of the removal of three-fold symmetry from the substrate top surface, microcrystals of α-Ta grown epitaxially over a-plane sapphire no longer have multiple choices of in-plane orientations. The α-Ta thus can be grown in single domains (see FIG. 1) with Ta (110) plane parallel to Al₂O₃ (1120) plane (see FIG. 2) and an in-plane alignment of Ta[111]//Al₂O₃ [0001) (see FIG. 3).

More specifically, FIG. 1 depicts a cross-sectional high-angle annular dark-field scanning transmission electron microscopy (HAADF-STEM) image of a Ta film (top, light gray) over a-plane sapphire substrate (bottom, dark gray), showing near perfect lattice matching. FIG. 2 depicts a graph illustrating an X-ray diffraction pattern showing the epitaxial growth of α-Ta on a-plane sapphire, with Ta (110) plane parallel to Al₂0₃ (1120) plane. FIG. 3 depicts an illustration of an atomic arrangement 10 at the interface between α-Ta 12 and a-plane sapphire 14, with Ta (110) plane 16 parallel to Al₂0₃ (1120) plane 18 and an in-plane alignment of Ta[111]//Al₂0₃[0001]. The arrangement 10 of FIG. 3 includes Oxygen 20.

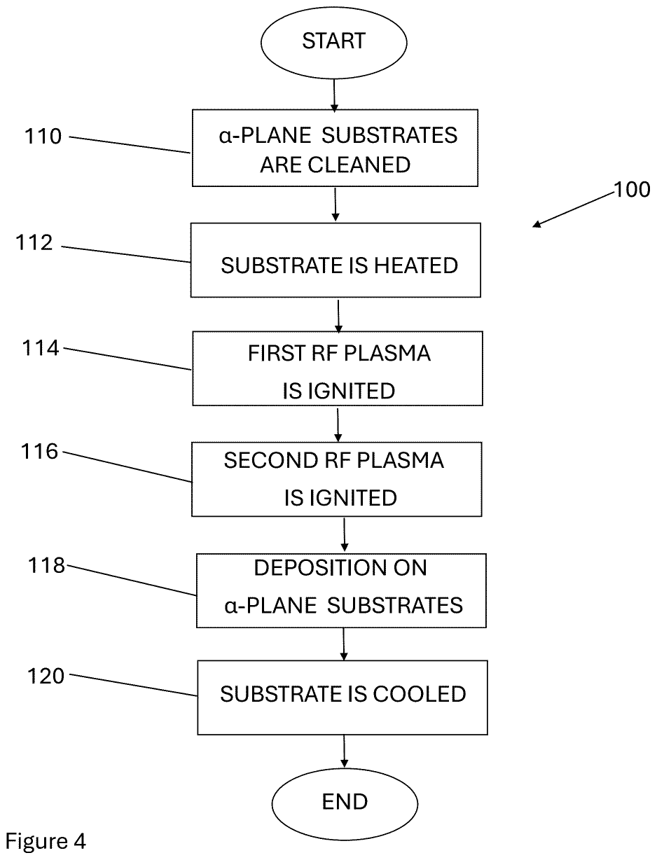

In accordance with one or more embodiments illustrated in FIG. 4, a method of producing a thin film tantalum (Ta) on a substrate, generally designated 100, and includes a-plane sapphire substrates that are cleaned, block 110, by oxygen plasma ashing for a few minutes for example, to remove organic contaminants, forming a cleaned substrate. The cleaned substrate may be loaded into the chamber of a sputtering tool pumped to a predetermined based pressure of about 3E⁻⁷ Torr or lower. The cleaned substrate is then heated, block 112, to a predetermined temperature of about 500-700° C., for example, and in one or more embodiments, kept at that temperature for a predetermined first period of time to stabilize, 10-30 minutes for example, forming a stabilized cleaned substrate. Embodiments are contemplated in which argon gas is introduced to the chamber at a stable flow rate to bring the pressure to 5-10 mTorr, for example.

In one embodiment of method 100, the pressure in the chamber is stabilized, a first radio frequency (RF) plasma is ignited around the stabilized cleaned substrate, block 114, and brought to a predetermined first power, of about 30 W for example. It should be appreciated that in one embodiment, this step is optional and may be skipped. The plasma achieves a final, in situ cleaning of the substrate, removing any minor contaminants that accumulated on the substrate during the brief period between oxygen plasma ashing and loading into sputtering chamber. The in situ plasma cleaning would last a few minutes. At its end, another, second, RF plasma is ignited around the stabilized cleaned substrate, block 116, at the Ta sputtering source for example, and is brought to a predetermined second power, of about 100 W for example.

It is contemplated that the sputtering source has a lid that is normally closed to block sputtered Ta atoms from reaching the substrate. In at least one embodiment, the sputtering source is left at the operational power, with lid closed, for a fourth period of time of about 2 minutes for example, to clean the Ta target surface. Subsequently, the lid is opened to start deposition on the a-plane sapphire substrate, block 118, at a very slow predetermined deposition rate, 0.4-0.5 A/sec for example. In one embodiment, the deposition lasts a predetermined second period of time, 80 minutes for example, to accumulate a Ta film of a predetermined thickness, of about 200 nm in thickness for example. Once the deposition is completed, the sputtering source, argon flow, and heating are all turned off. The substrate is left in vacuum for natural cooling, block 120. The substrate, now with the Ta film covered, is transferred out of the sputtering tool once it is cooled down to room temperature, which takes a third predetermined period of time, about 150 minutes for example, forming a substrate having a Ta film of a predetermined thickness. In embodiments, the Ta film is a fully epitaxial thin film on the substrate. The crystallinity and domain sizes of the Ta film are characterized by X-ray diffraction and transmission electron microscopy.

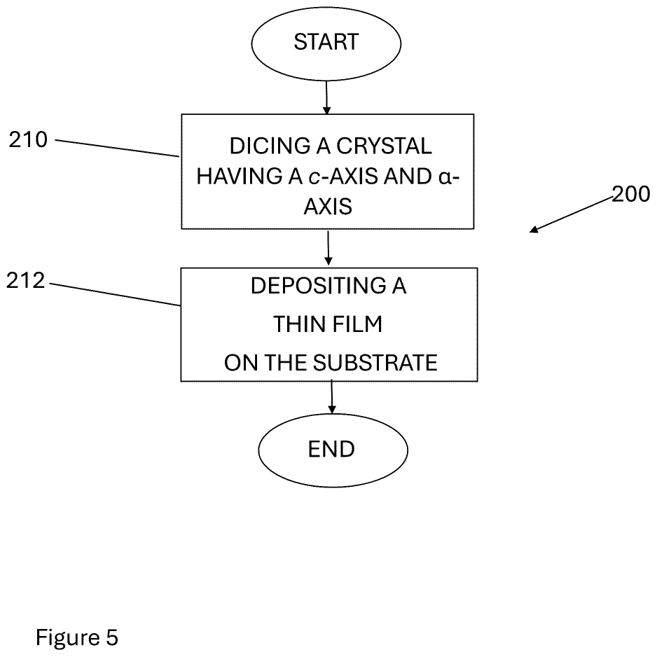

FIG. 5 depicts yet another method, generally designated 200, for producing thin film on a substrate. Method 200 includes dicing a crystal having a c-axis and an a-axis such that c-axis lies in an in-plane of the substrate and the a-axis lies perpendicular to the plane of the substrate; and depositing a thin film on the substrate such that the a-axis of the substrate is better matched to a lattice of the thin film. In at least one embodiment, the thin film comprises an epitaxial α-Ta thin film and the substrate comprises an a-plane sapphire substrate.

In embodiments of the invention described herein, an insulating substrate used in a superconducting transom qubit comprises an a-plane sapphire substrate having at least a c-axis lying in-plane sapphire substrate and a-axis perpendicular to the sapphire surface; and an epitaxial α-Ta thin film on the sapphire substrate, such that a-plane has a regular symmetry matted to a lattice plane of the α-Ta thin film.

Having described the basic concept of the embodiments, it will be apparent to those skilled in the art that the foregoing detailed disclosure is intended to be presented by way of example. Accordingly, these terms should be interpreted as indicating that insubstantial or inconsequential modifications or alterations and various improvements of the subject matter described and claimed are considered to be within the scope of the spirited embodiments as recited in the appended claims. Additionally, the recited order of the elements or sequences, or the use of numbers, letters or other designations therefor, is not intended to limit the claimed processes to any order except as may be specified. All ranges disclosed herein also encompass any and all possible sub-ranges and combinations of sub-ranges thereof. Any listed range is easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as up to, at least, greater than, less than, and the like refer to ranges which are subsequently broken down into sub-ranges as discussed above. As utilized herein, the terms “about,” “substantially,” and other similar terms are intended to have a broad meaning in conjunction with the common and accepted usage by those having ordinary skill in the art to which the subject matter of this disclosure pertains. As utilized herein, the term “approximately equal to” shall carry the meaning of being within 15, 10, 5, 4, 3, 2, or 1 percent of the subject measurement, item, unit, or concentration, with preference given to the percent variance. It should be understood by those of skill in the art who review this disclosure that these terms are intended to allow a description of certain features described and claimed without restricting the scope of these features to the exact numerical ranges provided. Accordingly, the embodiments are limited only by the following claims and equivalents thereto. All publications and patent documents cited in this application are incorporated by reference in their entirety for all purposes to the same extent as if each individual publication or patent document were so individually denoted.

All numeric values are herein assumed to be modified by the term “about”, whether or not explicitly indicated. The term “about” generally refers to a range of numbers that one of skill in the art would consider equivalent to the recited value (e.g., having the same function or result). In many instances, the terms “about” may include numbers that are rounded to the nearest significant figure.

The recitation of numerical ranges by endpoints includes all numbers within that range (e.g. 1 to 5 includes 1, 1.5, 2, 2.75, 3, 3.80, 4, and 5).

One skilled in the art will also readily recognize that where members are grouped together in a common manner, such as in a Markush group, the present invention encompasses not only the entire group listed as a whole, but each member of the group individually and all possible subgroups of the main group. Accordingly, for all purposes, the present invention encompasses not only the main group, but also the main group absent one or more of the group members. The present invention also envisages the explicit exclusion of one or more of any of the group members in the claimed invention.

1. A method for producing thin film tantalum (Ta) on a substrate, comprising:
cleaning the substrate, removing organic contaminants, forming a cleaned substrate;
heating the cleaned substrate to a predetermined first temperature for a predetermined first period of time, forming a stabilized cleaned substrate;
igniting a first radio frequency (RF) plasma around the stabilized cleaned substrate at a predetermined first power;
igniting a second radio frequency (RF) plasma around the stabilized cleaned substrate at a predetermined second power;
depositing Ta on the stabilized cleaned substrate at a predetermined deposition rate for a predetermined second period of time, forming a substrate having a Ta film of a predetermined thickness; and
cooling the substrate having a Ta film of the predetermined thickness for a predetermined third period of time, producing a fully epitaxial thin film (Ta) on the substrate.

2. The method of claim 1 wherein the substrate is a sapphire substrate.

3. The method of claim 1 wherein cleaning the substrate comprises performing oxygen plasma ashing.

4. The method of claim 1 wherein heating the cleaned substrate includes loading the cleaned substrate into a chamber of a sputtering tool that has been pumped to a predetermined based pressure, and heating the cleaned substrate to the predetermined first temperature for the predetermined first period of time.

5. The method of claim 4 wherein the predetermined based pressure is about 3E⁻⁷ Torr or lower, the predetermined first temperature is between about 500° C. and 700° C., and the predetermined first period of time is between about 10 and 30 minutes.

6. The method of claim 4 further comprising introducing argon gas into the chamber at a stable flow rate changing the predetermined based pressure to a second predetermined pressure.

7. The method of claim 6 wherein the second predetermined pressure is between about 5 and 10 mTorr.

8. The method of claim 1 wherein the predetermined first power is about 30 W.

9. The method of claim 1 wherein the predetermined second power is about 100 W.

10. The method of claim 4 where depositing Ta on the stabilized cleaned substrate at a predetermined deposition rate for a predetermined second period of time, forming the substrate having the Ta film of the predetermined thickness comprises sealing the chamber for a fourth period of time.

11. The method of claim 10 wherein the fourth period of time is about 2 minutes.

12. The method of claim 11 further comprises unsealing the chamber, initializing deposition of Ta on an a-plane of the substrate.

13. The method of claim 12 wherein the predetermined deposition rate comprises between about 0.4 and 0.5 A/sec, the predetermined second period of time comprises about 80 minutes, and the predetermined thickness comprises about 200 nm.

14. The method of claim 4 wherein cooling the substrate having the Ta film of the predetermined thickness for a predetermined third period of time, producing the fully epitaxial thin film (Ta) on the substrate comprises leaving the substrate having the Ta film in a vacuum for the predetermined third period of time.

15. The method of claim 14 wherein the third period of time comprises about 150 minutes.

16. A method for producing thin film on a substrate, comprising:
dicing a crystal having a c-axis and an a-axis such that c-axis lies in an in-plane of the substrate and the a-axis lies perpendicular to the plane of the substrate; and
depositing a thin film on the substrate such that the a-axis of the substrate is matched to a lattice of the thin film.

17. The method of claim 16 wherein the thin film comprises an epitaxial α-Ta thin film and the substrate comprises an a-plane sapphire substrate.

18. An insulating substrate used in a superconducting transom qubit, the insulating substrate comprising:
an a-plane sapphire substrate having at least a c-axis lying in-plane sapphire substrate and a-axis perpendicular to the sapphire surface; and
an epitaxial α-Ta thin film on the sapphire substrate, such that a-plane has a regular symmetry matted to a lattice plane of the α-Ta thin film.
